(19) United States
(12) Patent Application Publication
(10) Pub. No.: US 2025/0318201 A1
(43) Pub. Date: Oct. 9, 2025

(54) BACKSIDE GATE TIE DOWN THROUGH BACKSIDE POWER BAR

(71) Applicant: International Business Machines Corporation, Armonk, NY (US)

(72) Inventors: Lijuan Zou, Slingerlands, NY (US); Tao Li, Slingerlands, NY (US); Ruilong Xie, Niskayuna, NY (US); Jingyun Zhang, Albany, NY (US)

(21) Appl. No.: 18/631,011

(22) Filed: Apr. 9, 2024

(51) Int. Cl. H01L 29/786; H01L 21/8234; H01L 23/528; H01L 27/088; H01L 29/06; H01L 29/423; H01L 29/66; H01L 29/775

(52) U.S. Cl. CPC H10D 30/6757; H01L 23/5286; H10D 30/014; H10D 30/43; H10D 30/6735; H10D 62/121; H10D 64/017; H10D 84/013; H10D 84/0149; H10D 84/038; H10D 84/83

(57) ABSTRACT

Techniques for forming backside gate tie down through a backside power bar are provided. In one aspect, a semiconductor device is provided, including: at least one FET (e.g., a first FET, a second FET, etc.) on a frontside of a wafer; a backside power rail on a backside of the wafer; and a backside power bar connecting the backside power rail to a source/drain region of the at least one FET from the frontside of the wafer and a gate of the at least one FET from the backside of the wafer. A method of fabricating a semiconductor device is also provided.

### BACKGROUND

The present invention relates generally to the electrical, electronic and computer arts and, more particularly, to integrated circuits such as complementary metal oxide semiconductor (CMOS) integrated circuits.

Conventional approaches for isolating regions of a continuous active area in a CMOS design oftentimes involve specifically placing a sacrificial gate within an isolation region, patterning and etching off the sacrificial gate, and back filling with dielectric. This approach is referred to as a single diffusion break or SDB.

However, implementing SDB technology involves performing multiple high-aspect-ratio etches, followed by dielectric fill and chemical-mechanical planarization (CMP) processes, thereby increasing production costs and complexity. Further, etching in this manner can undesirably damage the adjacent source/drain region epitaxial material.

### BRIEF SUMMARY

Principles of the invention provide techniques for backside gate tie down through a backside power bar. In one aspect, a semiconductor device is provided. The semiconductor device includes: at least one field-effect transistor (FET) on a frontside of a wafer; a backside power rail on a backside of the wafer; and a backside power bar connecting the backside power rail to a source/drain region of the at least one FET from the frontside of the wafer and a gate of the at least one FET from the backside of the wafer.

In another aspect, another semiconductor device is provided. The semiconductor device includes: at least a first FET and a second FET on a frontside of a wafer, where the first FET and the second FET each includes a channel, a gate on the channel, and source/drain regions on opposite ends of the channel; a backside power rail on a backside of the wafer; and a backside power bar present between the first FET and the second FET, where the backside power bar connects the backside power rail to a given one of the source/drain regions of the first FET from the frontside of the wafer and the gate of the first FET from the backside of the wafer.

In yet another aspect, a method of fabricating a semiconductor device is provided. The method includes: forming at least a first FET and a second FET on a frontside of a wafer, where the first FET and the second FET each includes a channel, a gate on the channel, and source/drain regions on opposite ends of the channel; forming a gate cut opening between the gate of the first FET and the gate of the second FET; forming a power via in the gate cut opening from the frontside of the wafer; forming a backside power bar in the gate cut opening from a backside of the wafer, where the backside power bar directly contacts a portion of a sidewall of the gate of the first FET.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
An effective backside gate tie down scheme without the need for a deep power via connection;
Formation of a backside power bar in a gate cut opening having a unique gate tie down extension formed from a backside of a wafer which provides a direct gate connection;
Implementation of a unique bi-layer dielectric in the gate cut opening to enable formation of a power via from a frontside of the wafer, and the self-aligned formation of the backside power bar and a backside power rail from the backside of the wafer.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-68 show exemplary steps in the fabrication of an exemplary semiconductor device, according to aspects of the invention, wherein FIGS. 1, 5, 9, 13, 17, 21, 25, 29, 33, 37, 41, 45, 49, 53, 57, 61, and 65 are top views and the remaining figures are cross-sectional views along the indicated section lines.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

One or more embodiments provide a backside gate tie down through the use of a backside power bar. Doing so advantageously provides an efficient and effective technique for defining field-effect transistor (FET) gates over a continuous active area, while avoiding use of a single diffusion break or SDB as with conventional approaches. Namely, as highlighted above, forming an SDB undesirably involves multiple high-aspect-ratio etches, followed by dielectric fill and chemical-mechanical planarization (CMP) processes, thereby increasing both design complexity and costs. Further, issues such as SDB etch-induced source/drain region epitaxy damage can be avoided.

The use of a frontside gate tie down has been implemented in some conventional approaches. While avoiding the drawbacks associated with SDB, the frontside gate tie down still ends up occupying a significant amount of area on the frontside of the production wafer. Furthermore, a frontside gate tie down typically requires that a very deep frontside etch be performed between adjacent source/drain regions (i.e., to below the depth of the source/drain region epitaxy) in order to access a buried power supply through a deep power via. Any misalignment of this deep power via can undesirably lead to a gate short. While reducing the size of the deep power via can help avoid a short, doing so undesirably increases the resistance. Conversely, while increasing the size of the deep power via reduces resistance, doing so can undesirably increase the power via-to-gate capacitance, as well as the risk of shorting to the gate.

Notably, the exemplary embodiments avoid such drawbacks by implementing a backside gate tie down approach using a backside power bar within a gate cut region, which connects a backside power rail to both a source/drain region (through a power via) and a gate of a corresponding FET device. As will be described in detail below, the present backside power bar contacts the power via from the backside of the device, thereby avoiding the need for a deep frontside etch, and hence mitigating the risk of a gate short.

Further, the backside power bar serves to increase the size of the overall connection to the backside power rail. Doing so advantageously lowers the contact resistance. However, since the backside power bar contacts the power via from the backside of the device, there is no corresponding increase in the power via-to-gate capacitance at the frontside of the device.

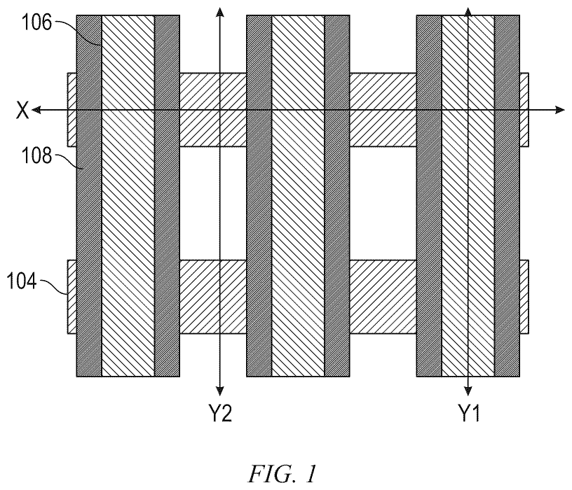

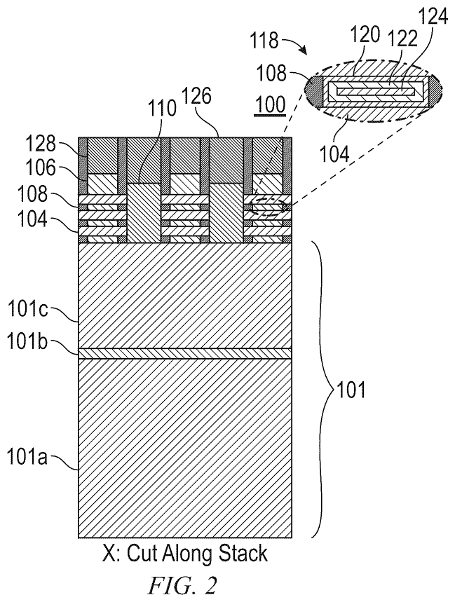

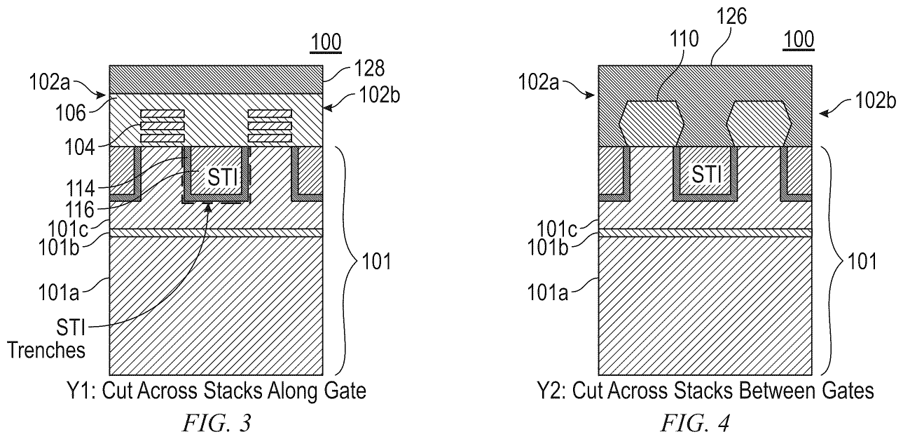

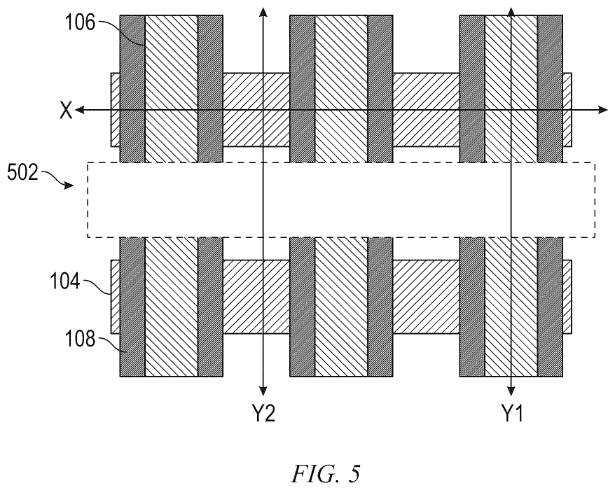

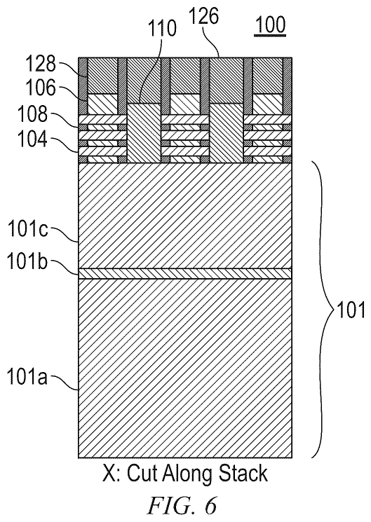

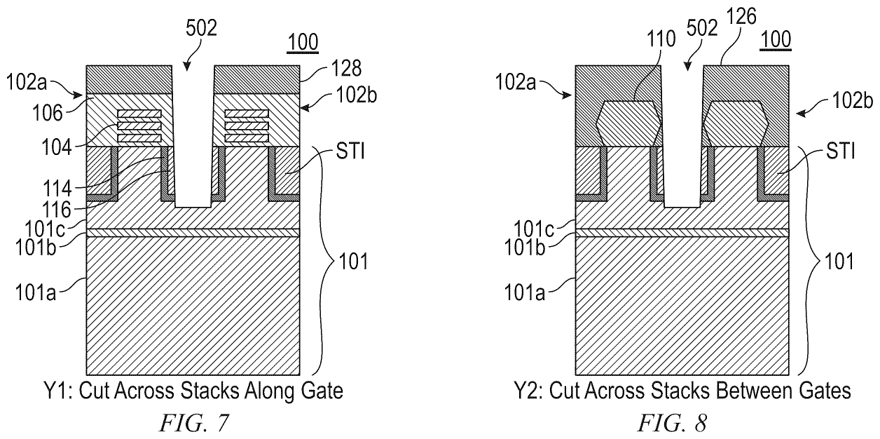

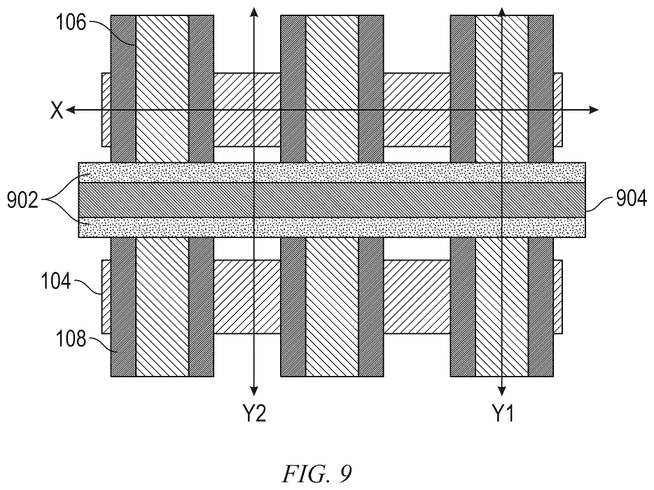

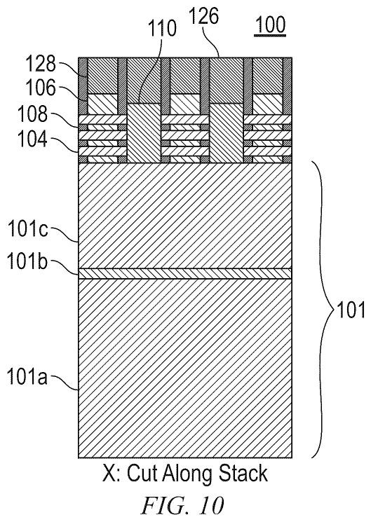

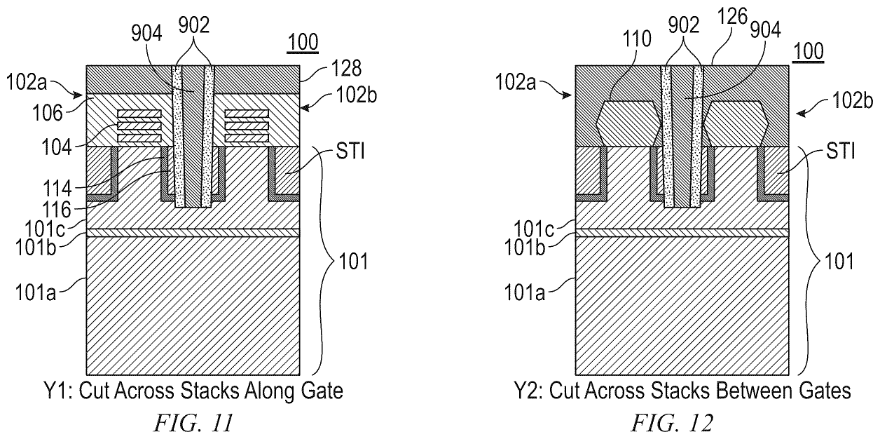

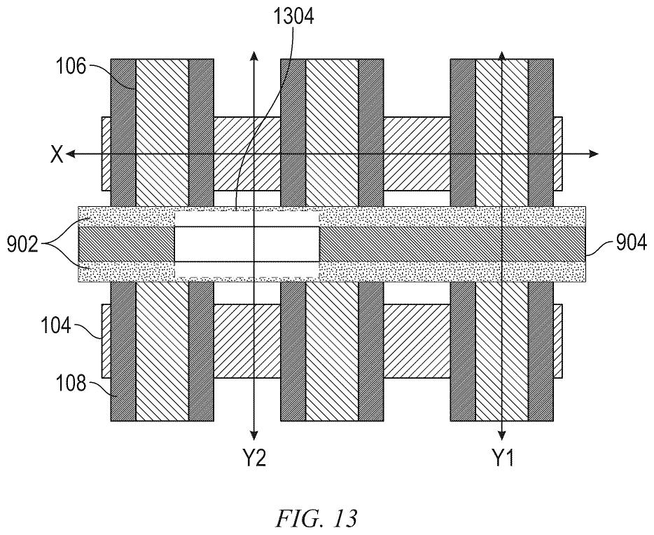

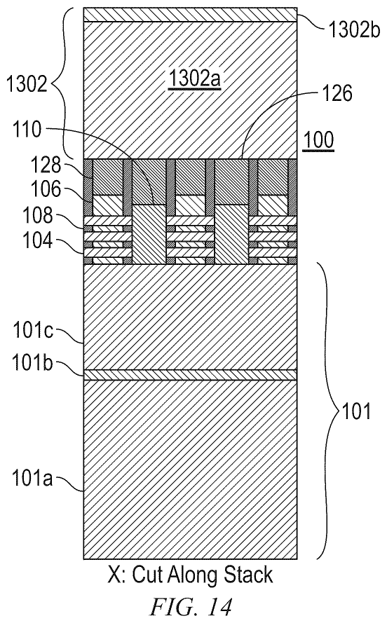

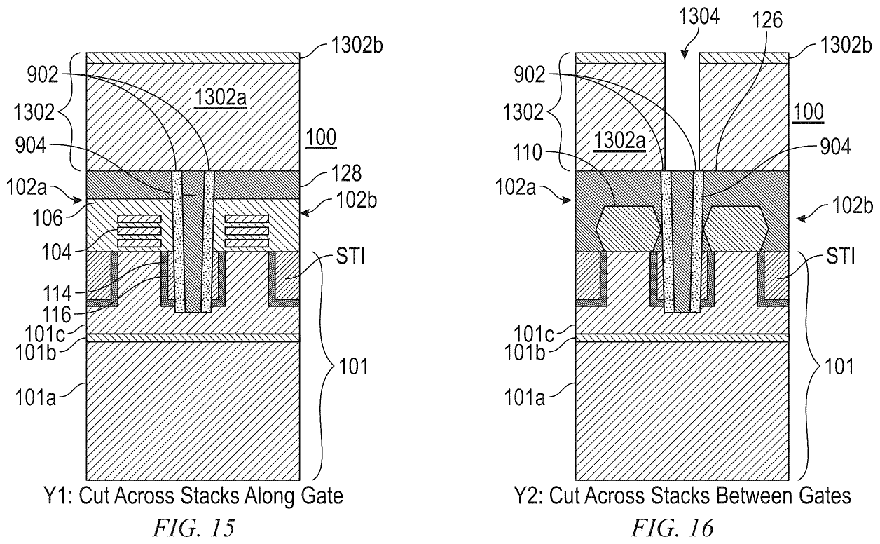

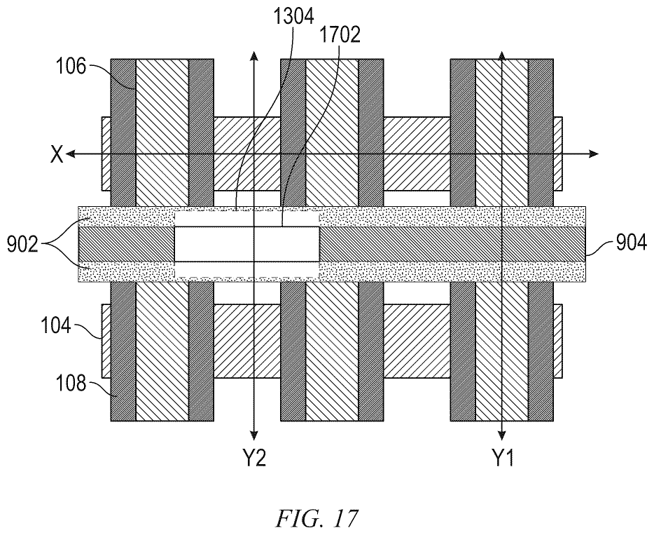

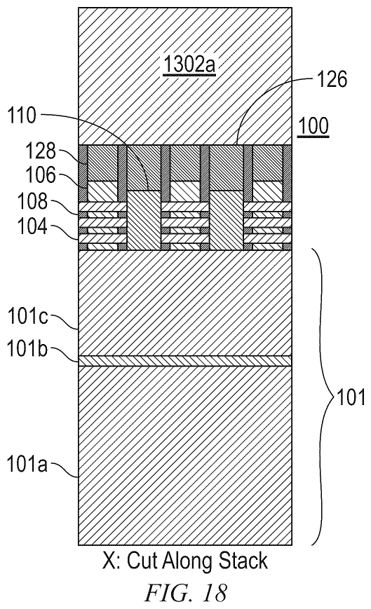

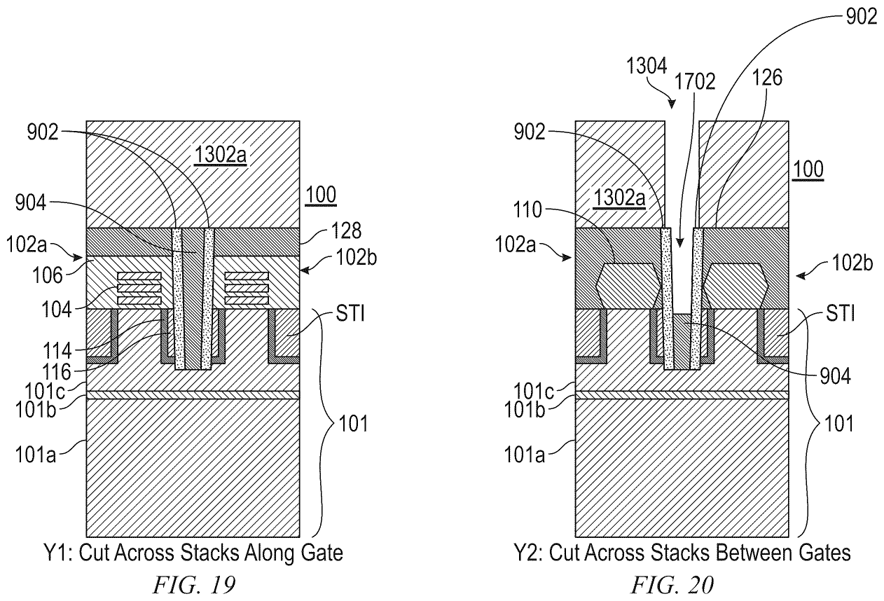

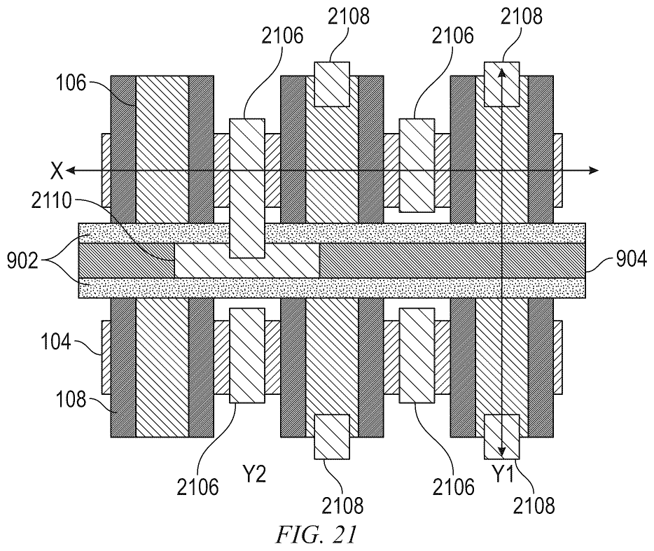

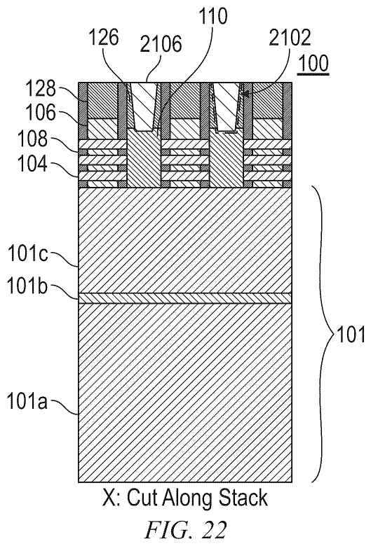

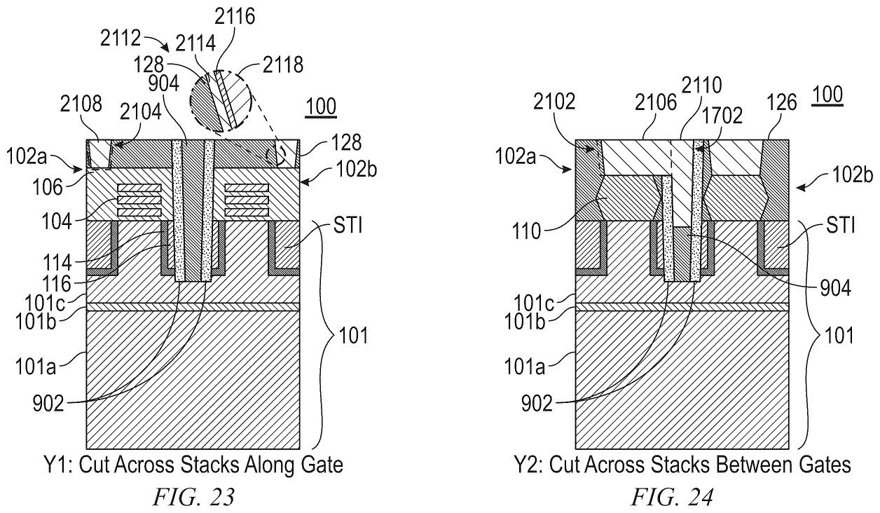

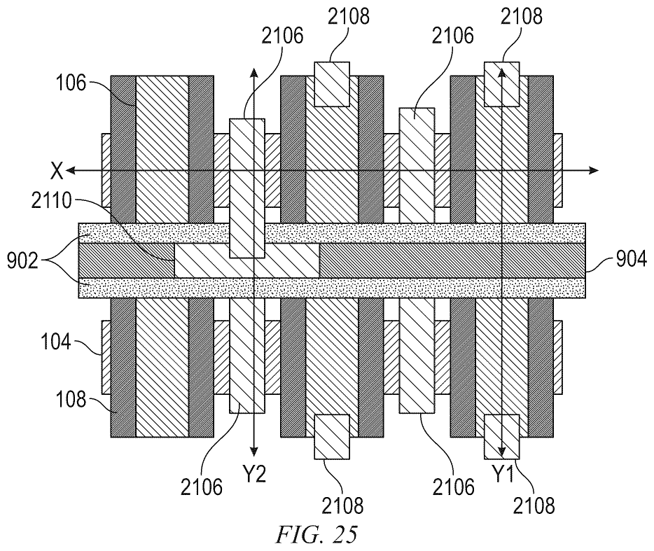

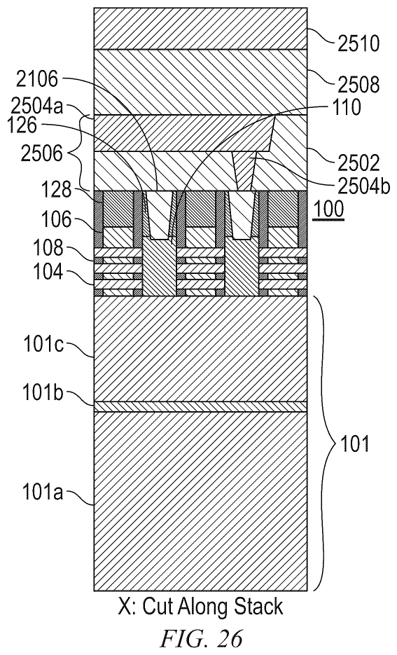

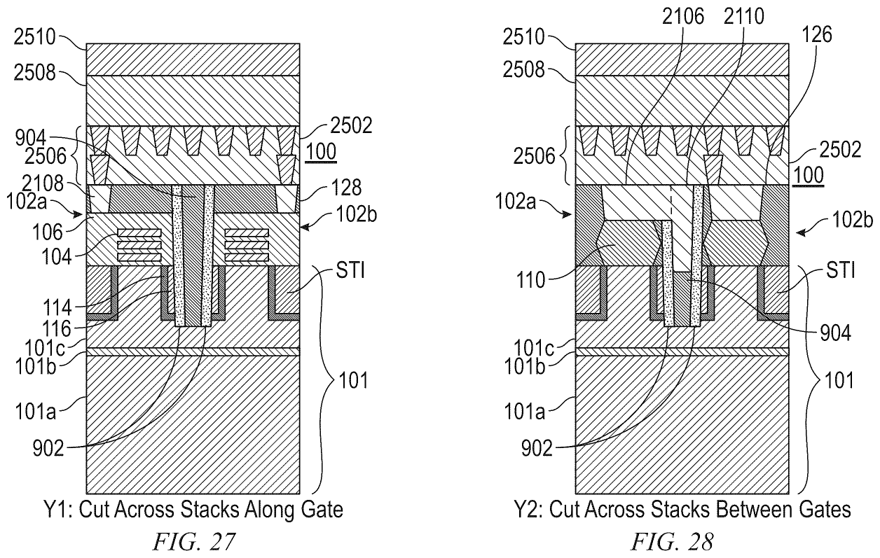

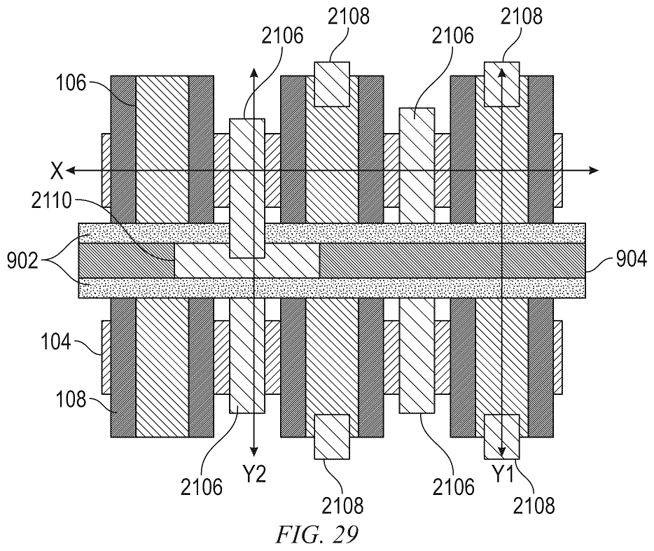

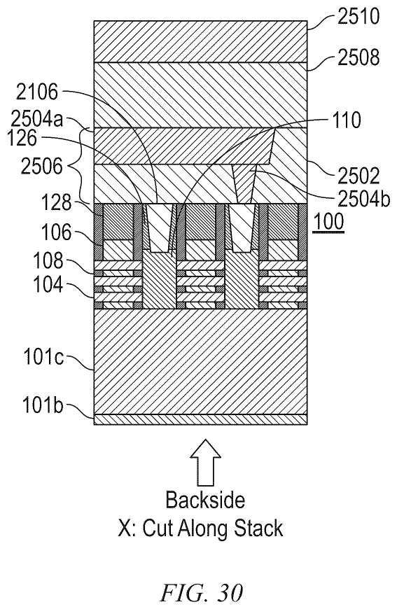

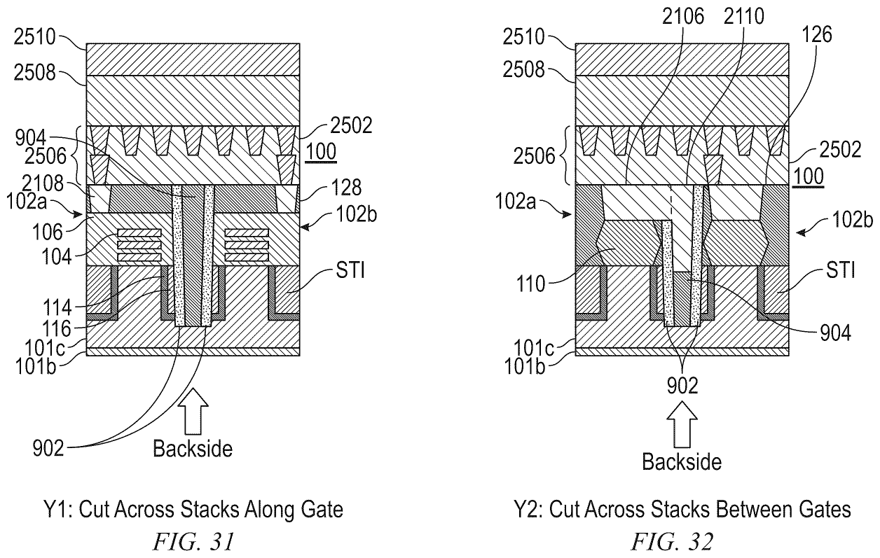

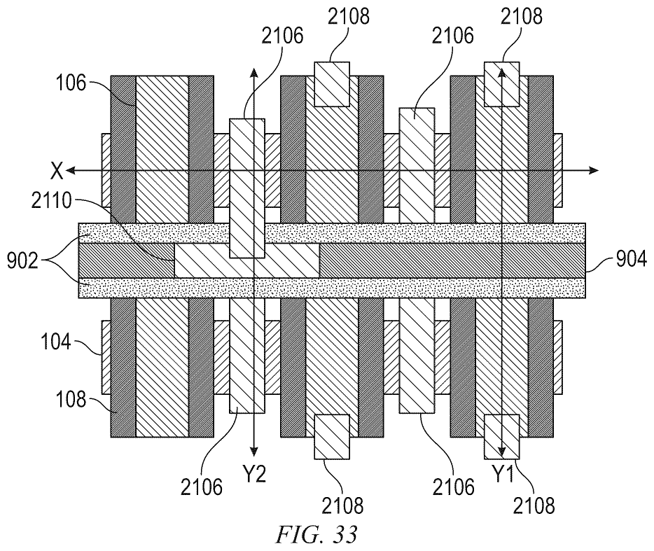

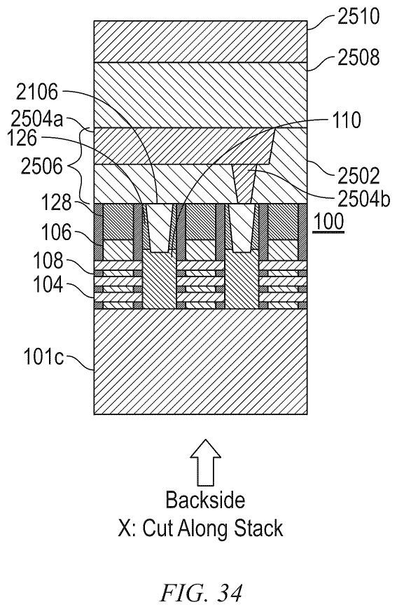

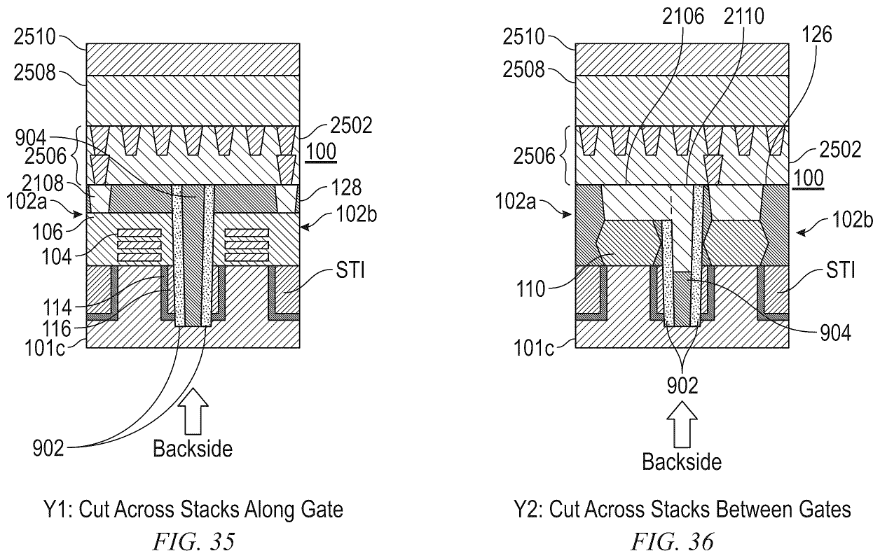

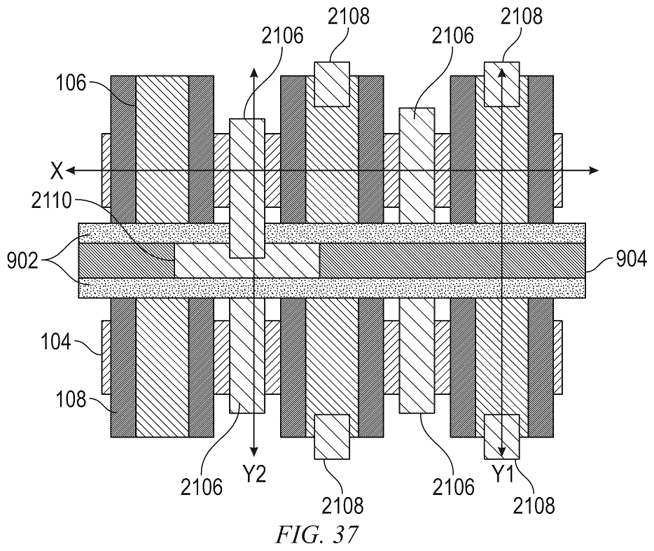

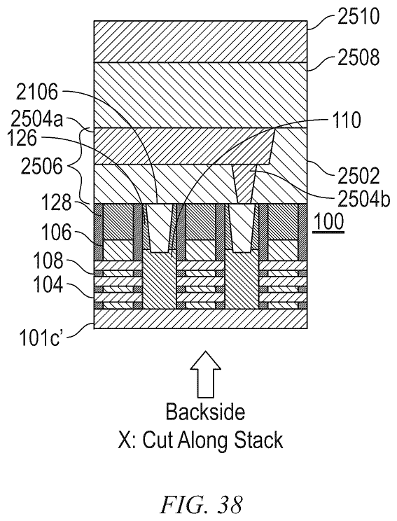

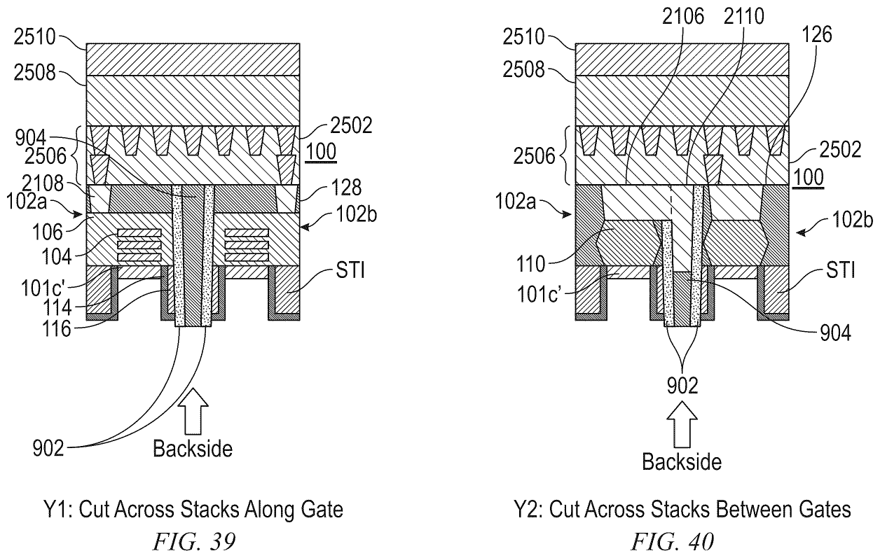

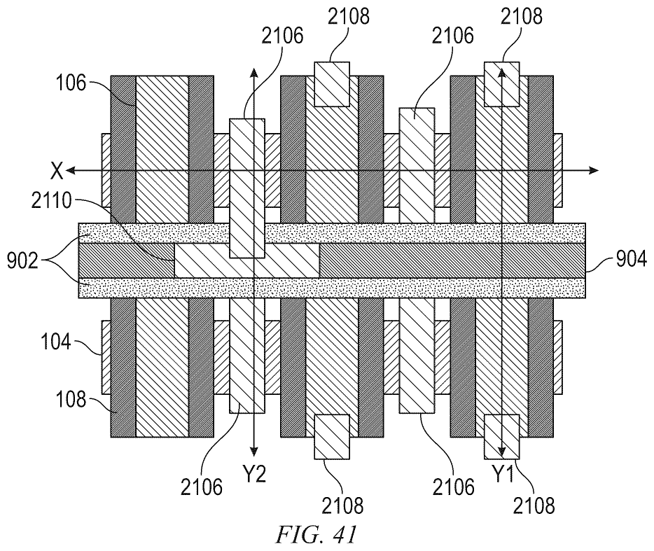

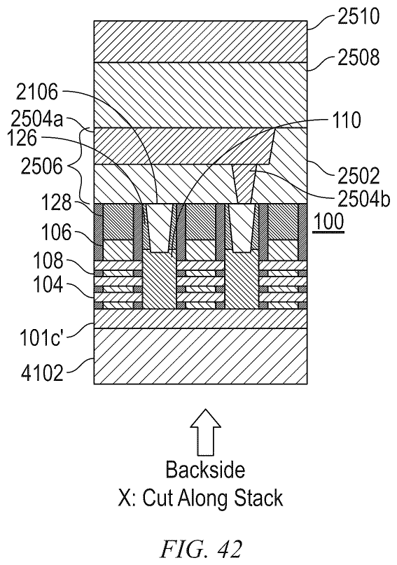

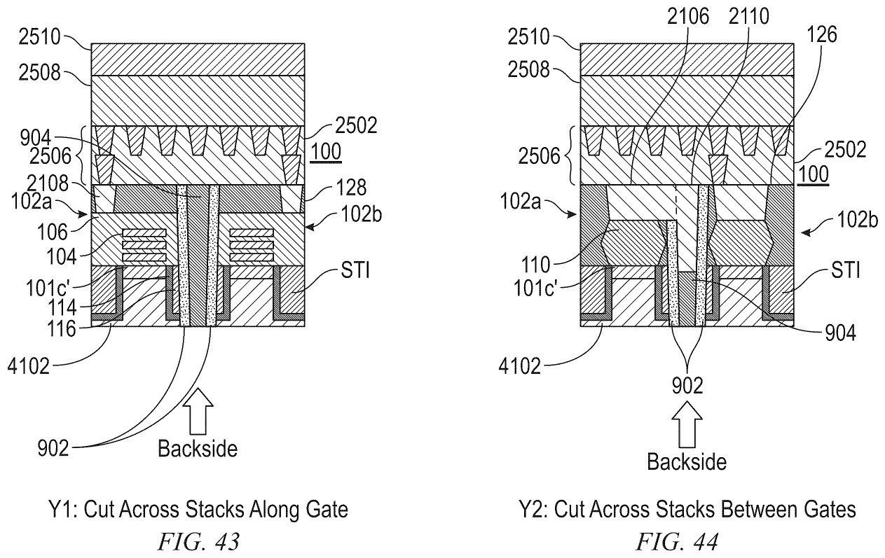

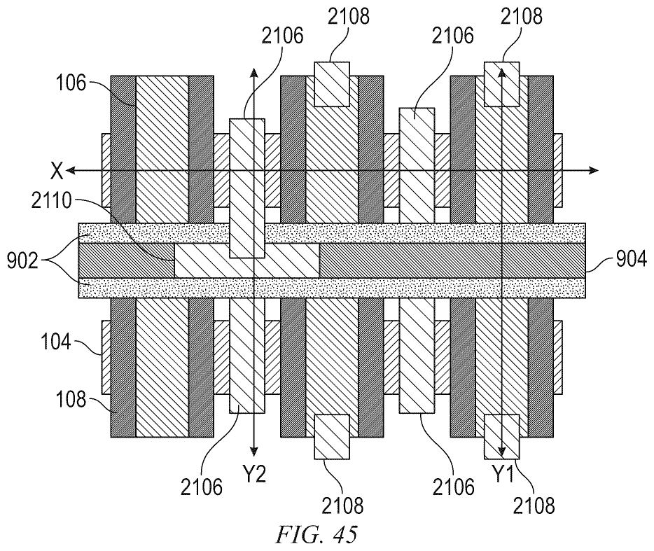

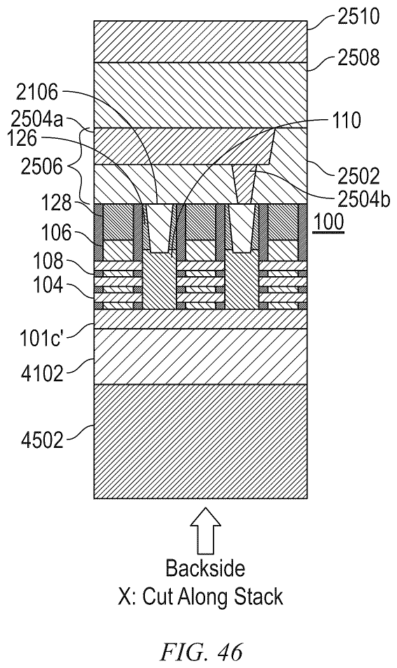

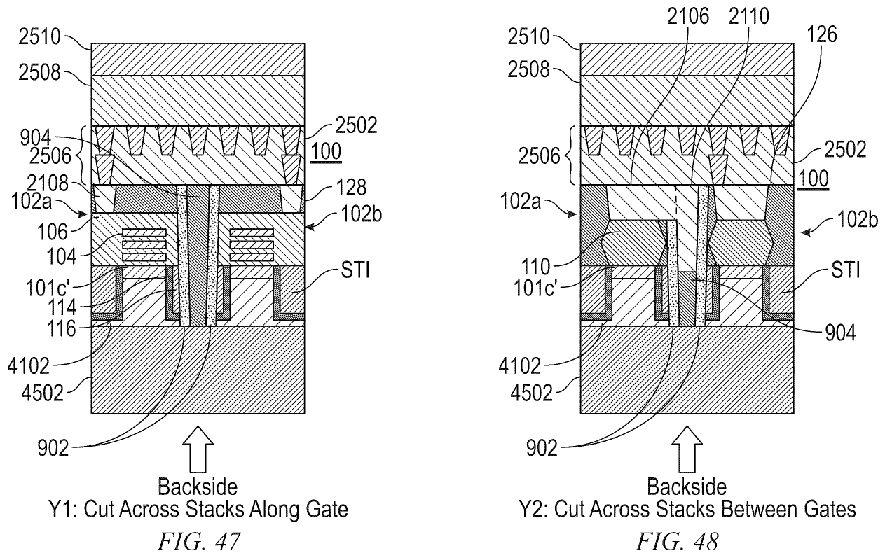

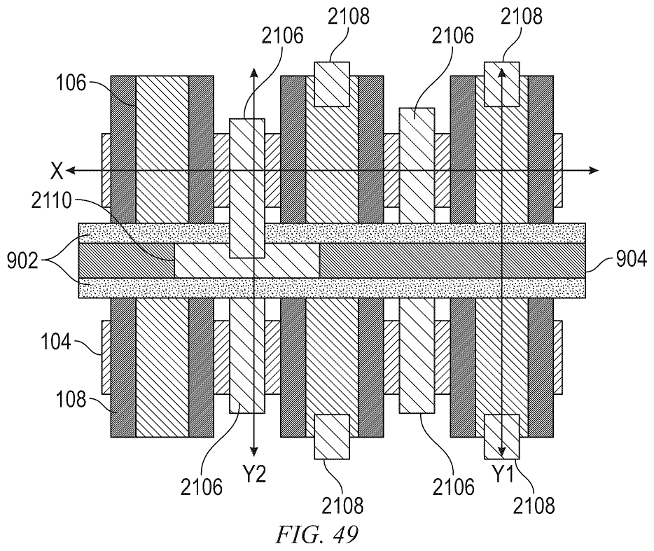

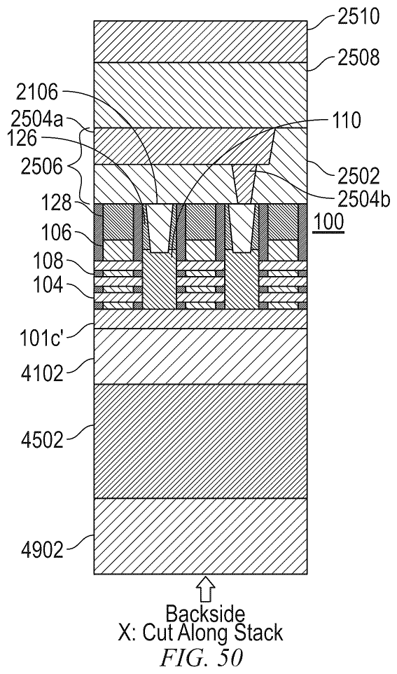

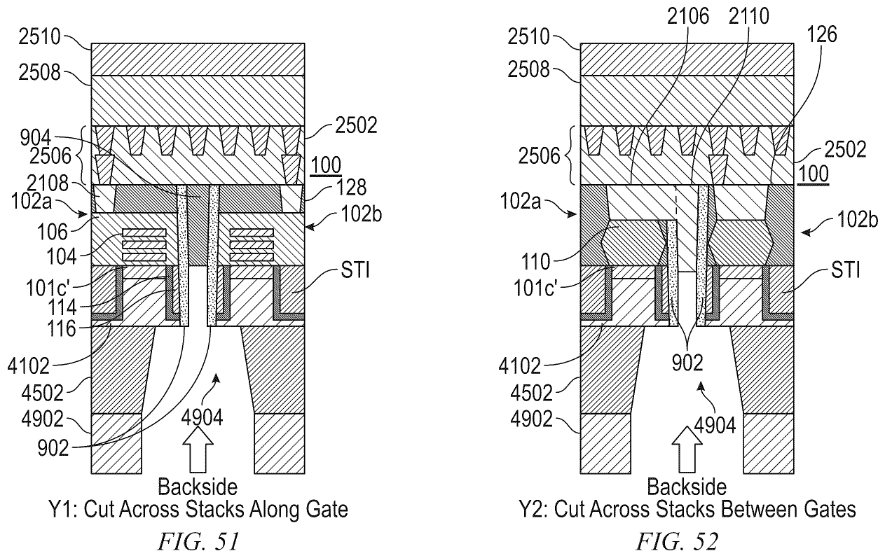

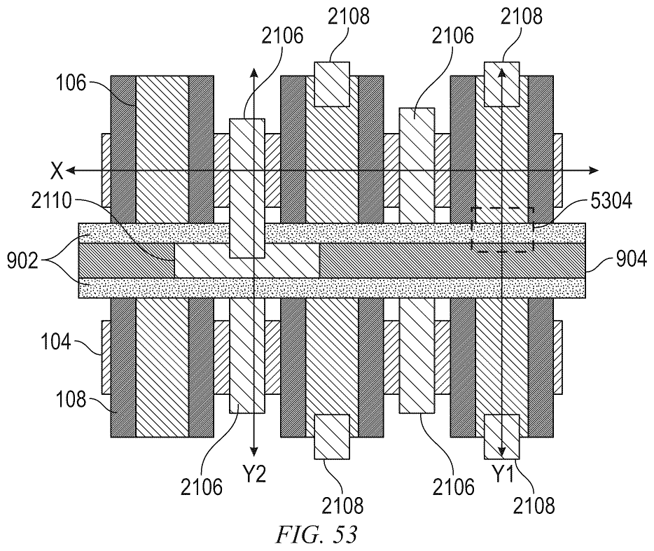

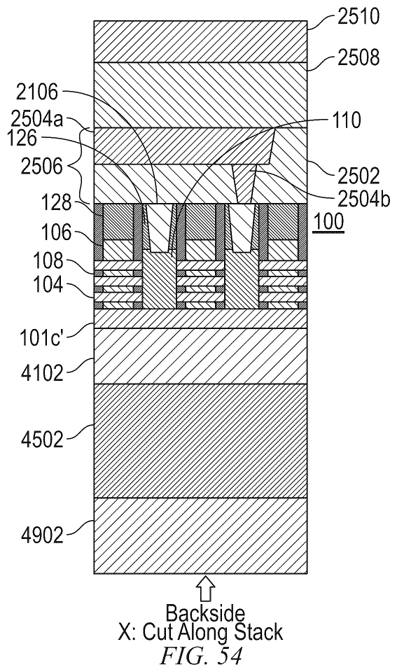

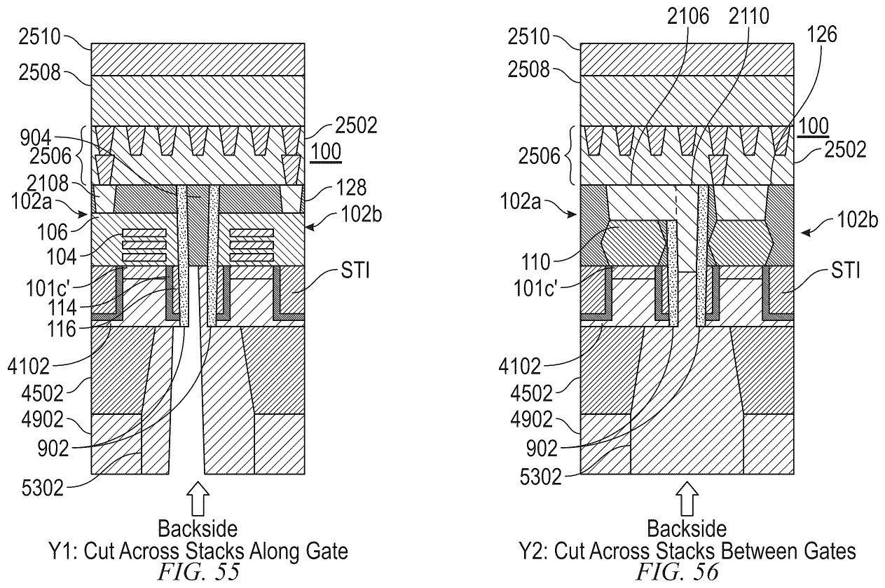

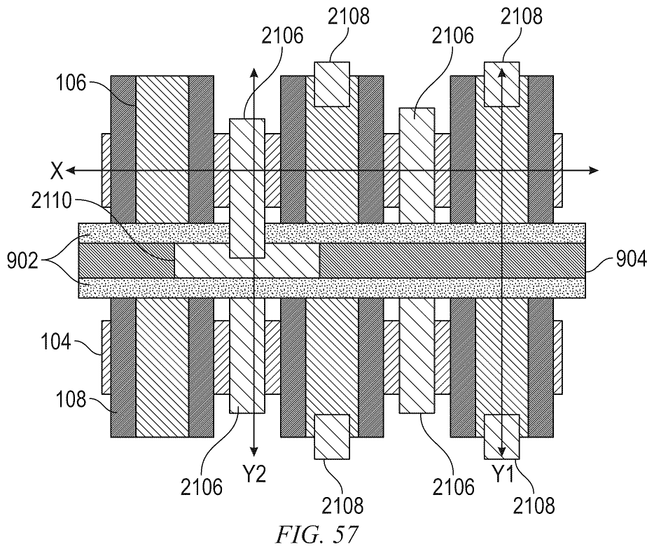

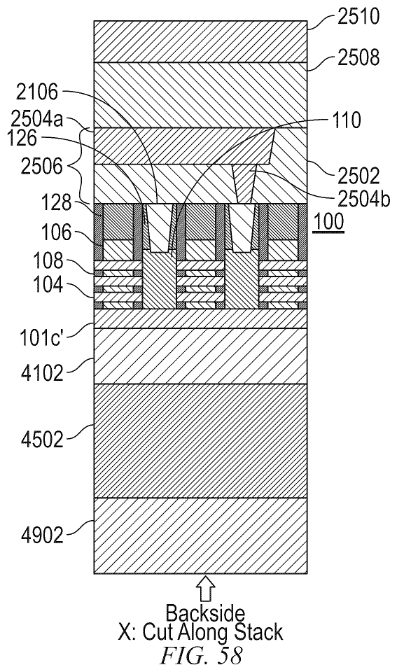

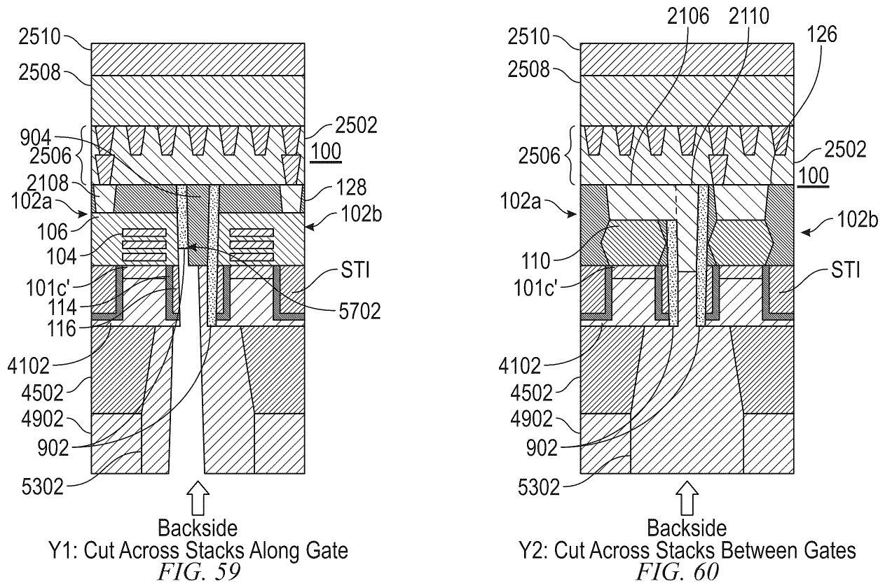

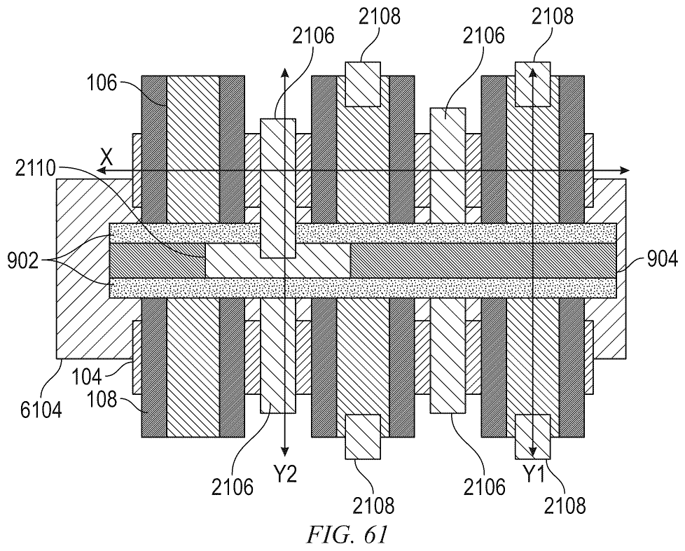

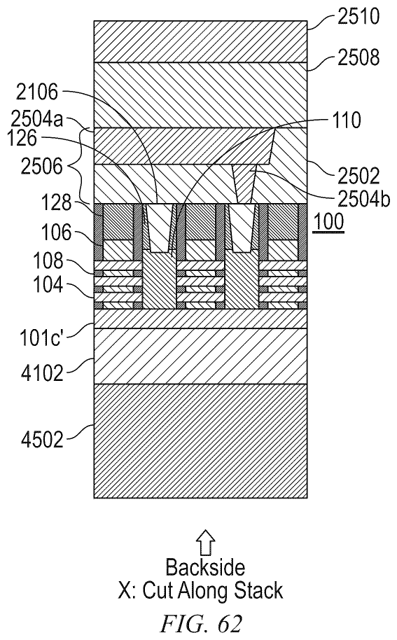

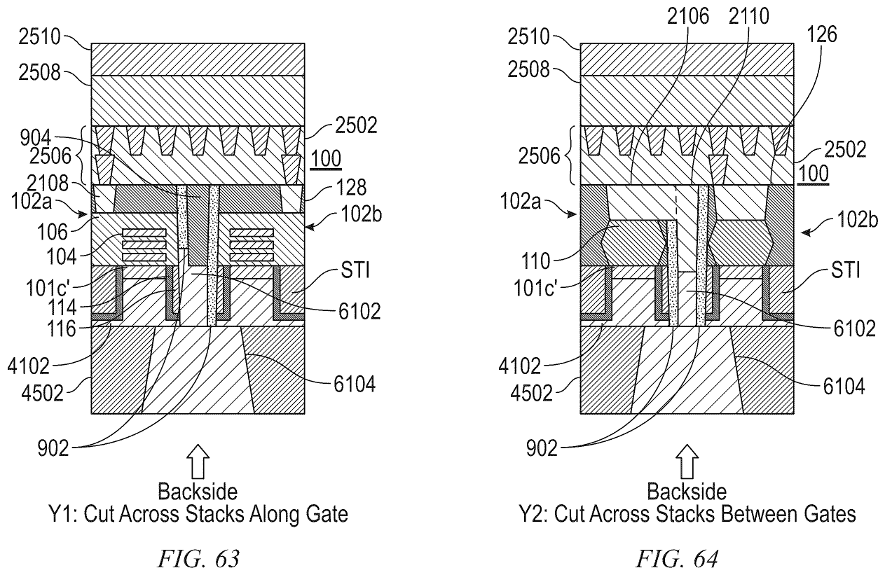

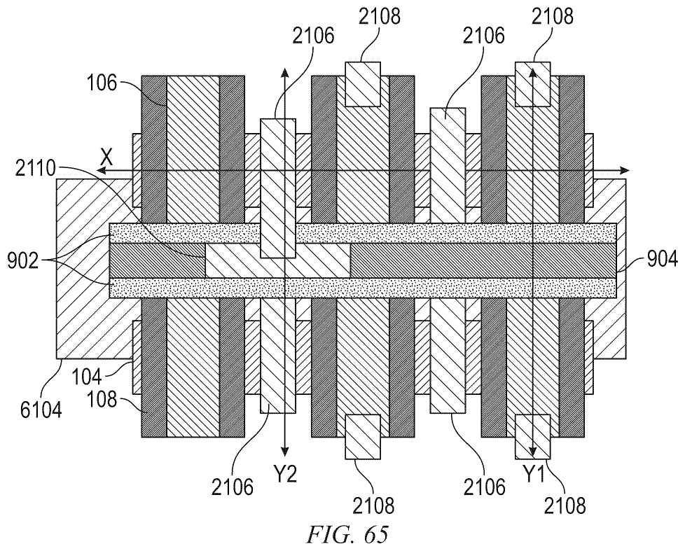

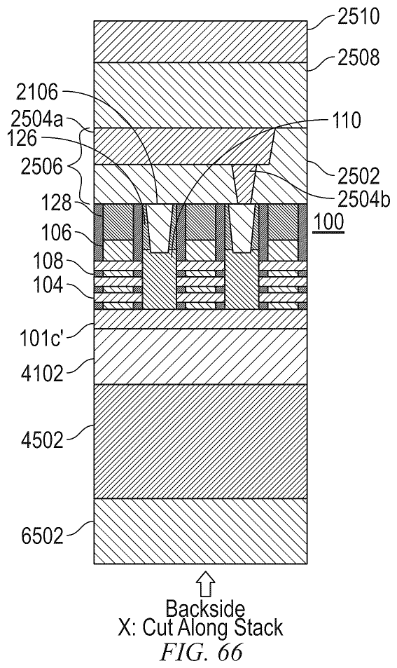

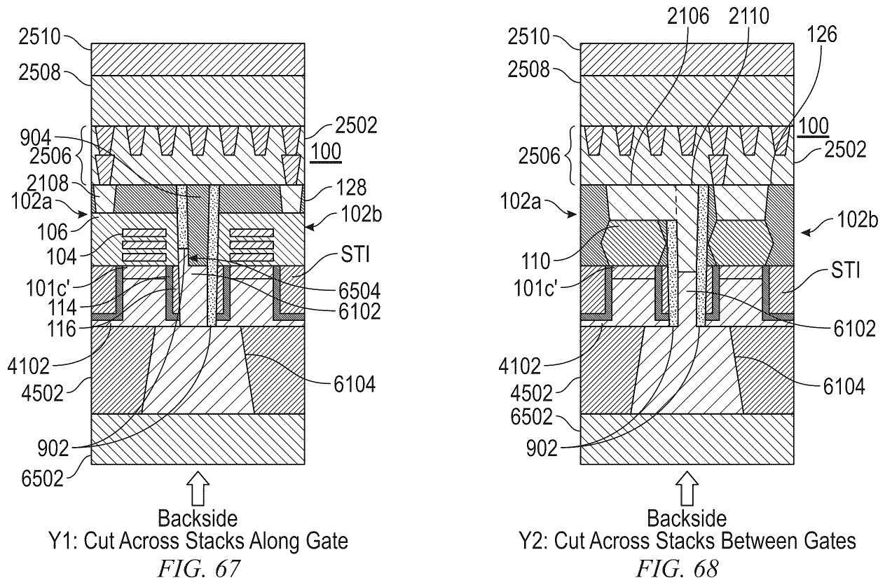

Consider an exemplary methodology for fabricating a semiconductor device 100 in accordance with the present techniques, which is now described by way of reference to FIGS. 1-68. For instance, referring to FIG. 1 (a top-down view), FIG. 2 (an X cross-sectional view), FIG. 3 (a Y1 cross-sectional view) and FIG. 4 (a Y2 cross-sectional view), the process begins with the formation of at least one FET, e.g., (first) FET 102a, (second) FET 102b, etc., on a frontside of a wafer 101. According to an exemplary embodiment, each FET 102a, 102b, etc. includes a stack of active layers 104 that serve as a channel, a gate 106 on the channel that surrounds each of the active layers in a gate-all-around or GAA configuration, and source/drain regions 110 at opposite ends of the active layers 104 (channel) and offset from the gate 106 by spacers 108.

As shown particularly in FIG. 1, semiconductor device 100 can include multiple stacks of active layers 104 and multiple gates 106, oriented orthogonal to one another, and extending arbitrarily along an X-direction and a Y-direction, respectively. Accordingly, the X cross-sectional views provided herein represent cuts through the semiconductor device 100 in the X-direction, i.e., along one of the stacks of active layers 104. The Y1 cross-sectional views represent first cuts through the semiconductor device 100 in the Y-direction, i.e., across the stacks of active layers 104 along one of the gates 106. The Y2 cross-sectional views represent second cuts through the semiconductor device 100 in the Y-direction, i.e., across the stacks of active layers 104 between two of the gates 106. It is notable that, for ease and clarity of depiction, not all of the features of semiconductor device 100 are shown in FIG. 1, or in subsequent top-down views. In FIG. 1 for instance, structures such as (gate) dielectric caps, interlayer dielectric, etc. are not included in order to show the orientation of the stacks of active layers 104 and gates 106.

According to an exemplary embodiment, wafer 101 includes a substrate 101a, an etch stop layer 101b disposed directly on the substrate 101a, and a semiconductor layer 101c disposed directly on the etch stop layer 101b. As will be described in detail below, etch stop layer 101b will be used during removal of the substrate 101a from a backside of the wafer 101. By way of example only, etch stop layer 101b can have a thickness of from about 2 nanometers (nm) to about 50 nm. According to one exemplary embodiment, substrate 101a is a bulk semiconductor wafer, such as a bulk silicon (Si) wafer, and etch stop layer 101b is formed from silicon germanium (SiGe) that is epitaxially grown from the (Si) substrate 101a. In turn, semiconductor layer 101c (e.g., Si) can be epitaxially grown from the etch stop layer 101b.

According to another exemplary embodiment, etch stop layer 101b is an oxide layer. In that case, wafer 101 can be a semiconductor-on-insulator or SOI wafer. An SOI wafer includes an SOI layer separated from an underlying substrate by a buried insulator. When the buried insulator is an oxide, it is also referred to herein as a buried oxide or BOX. In the present example, the substrate, BOX, and SOI layer correspond to the substrate 101a, the (oxide) etch stop layer 101b, and the semiconductor layer 101c, respectively. As above, the SOI layer/semiconductor layer 101c can include any suitable semiconductor material(s), such as Si.

As shown in the figures, the active layers 104 are oriented horizontally (i.e., stacked) one on top of another on wafer 101. In one exemplary embodiment, the sacrificial and active layers are nanosheets. The term “nanosheet” as used herein, generally refers to a sheet or a layer having nanoscale dimensions. Further, the term “nanosheet” is meant to encompass other nanoscale structures such as nanowires. For instance, the term “nanosheet” can refer to a nanowire with a larger width, and/or the term “nanowire” can refer to a nanosheet with a smaller width, and vice versa.

As would be apparent to one of ordinary skill in the art, the active layers 104 can initially be separated by alternating sacrificial layers (not shown as they are no longer present at this point in the process flow). The term “sacrificial” as used herein refers to a material or structure that is used in one part of the process, and then later removed, in whole or in part, during fabrication of the semiconductor device. These sacrificial layers can then be removed in order to “release” the active layers 104 from the stack, thereby enabling the subsequently-formed gates 106 to surround a portion of each of the active layers 104 in a GAA configuration.

As such, the materials employed for the sacrificial layers and active layers 104 are such that the sacrificial layers can be removed selective to the active layers 104 during fabrication. For instance, according to an exemplary embodiment, the sacrificial layers are each formed from SiGe, while the active layers 104 are formed from Si. Etchants such as wet hot SC1, vapor phase hydrogen chloride (HCl), vapor phase chlorine trifluoride (ClF₃) and other reactive clean processes (RCP) are selective for etching of SiGe versus Si. This is, however, only one exemplary combination of sacrificial/active material that may be employed in accordance with the present techniques. For instance, by way of example only, the opposite configuration can instead be employed where the sacrificial layers are each formed from Si, and the active layers 104 are each formed from SiGe.

It is notable that the number of active layers 104 shown in the figures is provided merely as an example to illustrate the present techniques. For instance, embodiments are contemplated herein where more or fewer active layers 104 are present than shown. According to an exemplary embodiment, each of the active layers 104 has a thickness of from about 6 nm to about 25 nm.

Shallow trench isolation (STI) regions are present in the wafer 101 in between the stacks of active layers 104. As shown, for example, in FIG. 3 and FIG. 4, each of these STI regions includes a liner 114 disposed in/lining STI trenches in the wafer 101 in between the stacks of active layers 104, and a dielectric 116 such as an oxide (which may also be generally referred to herein as an “STI oxide”) disposed on the liner 114. Suitable materials for liner 114 include, but are not limited to, a thermal oxide or silicon nitride (SiN). A process such as chemical vapor deposition (CVD), atomic layer deposition (ALD), or physical vapor deposition (PVD) can be used to deposit the liner 114. Suitable STI oxides include, but are not limited to, oxide low-κ materials such as silicon oxide (SiOx) and/or oxide ultralow-κ interlayer dielectric (ULK-ILD) materials, e.g., having a dielectric constant κ of less than 2.7. Suitable ultralow-κ dielectric materials include, but are not limited to, porous organosilicate glass (pSiCOH). A process such as CVD, ALD or PVD can be used to deposit the STI oxide, after which the STI oxide can be planarized using a process such as CMP, and then recessed using a dry or wet etch process.

According to an exemplary embodiment, the source/drain regions 110 are each formed from an n-type or p-type in-situ doped (i.e., during growth) or ex-situ doped (e.g., via ion implantation) epitaxial material such as epitaxial Si, epitaxial SiGe, etc. Suitable p-type dopants include, but are not limited to, boron (B). Suitable n-type dopants include, but are not limited to, phosphorous (P) and/or arsenic (As).

In one illustrative, non-limiting embodiment, the gates 106 are replacement metal gates formed using a gate-last process. As would be apparent to one of ordinary skill in the art, a gate-last process involves forming sacrificial gates (not shown as they are no longer present at this point in the process flow) of, e.g., polysilicon and/or amorphous silicon, early on in the process which serve as a placeholder, and enable the placement of other FET components such as the source/drain regions. Advantageously, use of a gate-last process avoids exposing the replacement metal gate materials such as high-k dielectrics to potentially damaging conditions such as the high temperatures experienced during source/drain region formation. Accordingly, following placement of the source/drain regions, the sacrificial gates are then removed and replaced with the final or “replacement” gates of the device. When these replacement gates are metal, they are also referred to herein as “replacement metal gates.”

For instance, referring to magnified view 118 in FIG. 2, in this non-limiting example gates 106 include a (conformal) gate dielectric 120 disposed on the active layers 104/spacers 108, at least one workfunction-setting metal 122 disposed on the gate dielectric 120, and an optional (low-resistance) fill metal 124 disposed on the workfunction-setting metal(s) 122. According to an exemplary embodiment, gate dielectric 120 is a high-k material. The term “high-κ,” as used herein, refers to a material having a relative dielectric constant κ which is much higher than that of silicon dioxide (e.g., a dielectric constant κ=25 for hafnium oxide (HfO₂) rather than 4 for SiO₂). Suitable high-k gate dielectrics include, but are not limited to, hafnium oxide (HfO₂) and/or lanthanum oxide (La₂O₃). A process such as CVD, ALD, or PVD can be employed to deposit the gate dielectric 120. According to an exemplary embodiment, gate dielectric 120 has a thickness of from about 1 nm to about 5 nm. A reliability anneal can be performed following deposition of gate dielectric 120. In one exemplary embodiment, the reliability anneal is performed at a temperature of from about 500° C. to about 1200° C., for a duration of from about 1 nanosecond to about 30 seconds. Preferably, the reliability anneal is performed in the presence of an inert gas such as, but not limited to, nitrogen.

The at least one workfunction-setting metal 122 can include an n-type workfunction-setting metal and/or a p-type workfunction-setting metal. Suitable n-type workfunction-setting metals include, but are not limited to, titanium nitride (TiN), tantalum nitride (TaN) and/or aluminum (Al)-containing alloys such as titanium aluminide (TiAl), titanium aluminum nitride (TiAlN), titanium aluminum carbide (TiAlC), tantalum aluminide (TaAl), tantalum aluminum nitride (TaAlN), and/or tantalum aluminum carbide (TaAlC). Suitable p-type workfunction-setting metals include, but are not limited to, TiN, TaN, and/or tungsten (W). TiN and TaN are relatively thick (e.g., greater than about 2 nm) when used as p-type workfunction-setting metals. However, very thin TiN or TaN layers (e.g., less than about 2 nm) may also be used beneath Al-containing alloys in n-type workfunction-setting stacks to improve electrical properties such as gate leakage currents. Thus, there is some overlap in the exemplary n- and p-type workfunction-setting metals given above. A process such as CVD, ALD or PVD can be employed to deposit the workfunction-setting metal(s) 122, after which the metal overburden can be removed using a process such as CMP.

The optional fill metal 124 can be used to fill in any remaining spaces in the gates 106. Suitable (low-resistance) fill metals 124 include, but are not limited to, W, cobalt (Co), ruthenium (Ru) and/or Al which can be deposited using a process or combination of processes including, but not limited to, CVD, ALD, PVD, sputtering, plating, evaporation, ion beam deposition, electron beam deposition, laser assisted deposition, chemical solution deposition, etc.

The semiconductor device 100 is buried in an interlayer dielectric 126. Suitable interlayer dielectric 126 materials include, but are not limited to, SiN, silicon oxycarbide (SiOC) and/or oxide low-κ materials such as SiOx and/or oxide ULK-ILD materials such as pSiCOH, which can be deposited onto the semiconductor device 100 using a process such as CVD, ALD or PVD. According to an exemplary embodiment, the interlayer dielectric 126 is a different dielectric material from the STI regions (e.g., interlayer dielectric 126 can be SiN, and the dielectric 116 can be SiOx). Following deposition, the interlayer dielectric 126 can be planarized using a process such as CMP.

As shown in FIG. 2, the gates 106 are recessed below the tops of the spacers 108, and dielectric caps 128 are disposed over the (recessed) gates 106. Suitable dielectric cap 128 materials include, but are not limited to, SiOx and/or SiN, which can be deposited using a process such as CVD, ALD or PVD. Following deposition, the dielectric cap 128 material can be planarized using a process such as CMP.

Referring to FIG. 5 (a top-down view), FIG. 6 (an X cross-sectional view), FIG. 7 (a Y1 cross-sectional view) and FIG. 8 (a Y2 cross-sectional view), gate cut patterning is next performed to separate the gates 106 of adjacent ones of the FET 102a, 102b, etc. As shown in FIG. 5, this gate cut patterning creates at least one gate cut opening 502 between the gates 106 over adjacent stacks of the active layers 104.

Standard lithography and etching techniques can be employed to pattern the gate cut opening(s) 502. With standard lithography and etching techniques, a lithographic stack (not shown), e.g., photoresist/anti-reflective coating/organic planarizing layer, is used to pattern a hardmask (not shown) with the footprint and location of, in this case, each gate cut opening 502. Suitable hardmask materials include, but are not limited to, silicon nitride (SiN), silicon dioxide (SiO₂), titanium nitride (TiN) and/or silicon oxynitride (SiON). An etch is then performed to transfer the pattern from the hardmask to the underlying materials. Suitable etching processes include, but are not limited to, directional (anisotropic) etching processes such as reactive ion etching. Alternatively, the hardmask can be formed by other suitable techniques, including but not limited to, sidewall image transfer (SIT), self-aligned double patterning (SADP), self-aligned quadruple patterning (SAQP), and other self-aligned multiple patterning (SAMP).

The orientation of the gate cut opening 502 is further illustrated, for example, in FIG. 7 and FIG. 8. Notably, as shown in FIG. 7, the gate cut opening 502 now separates the gate 106 surrounding one stack of the active layers 104 from that surrounding the other adjacent stack. As highlighted above, it is within the region of this gate cut opening 502 that a backside power rail will connect to a backside power bar.

Referring to FIG. 9 (a top-down view), FIG. 10 (an X cross-sectional view), FIG. 11 (a Y1 cross-sectional view) and FIG. 12 (a Y2 cross-sectional view), a bi-layer dielectric is then formed in the gate cut opening 502. As its name implies, the bi-layer dielectric includes two distinct layers of dielectric materials, namely a first layer 902 of a first dielectric material which is deposited onto sidewalls of the gates 106 and lining the gate cut opening 502, and a second layer 904 of a second dielectric material deposited over the first layer 902, such that the first layer 902 of the first dielectric material is present along sidewalls of the gate cut opening 502 and the second layer 902 of the second dielectric material fully fills the gate cut opening 502 in between the first layer 902 of the first dielectric material. The first dielectric material and the second dielectric material are chosen to provide etch selectivity of one over the other. As will be described in detail below, doing so will permit the partial recess of the second layer 904 (selective to the first layer 902) and the frontside formation of a power via that is offset from the source/drain regions 110 by the first layer 902.

According to an exemplary embodiment, the first dielectric material (of first layer 902) is a nitride dielectric material such as SiN, whereas the second dielectric material (of second layer 904) is an oxide dielectric material such as SiO₂. A process such as CVD, ALD or PVD can be used to deposit the first layer 902. As-deposited the first layer 902 is conformal and will be present along the top, bottom and sidewalls of the gate cut opening 502. However, a directional (anisotropic) etching process such as reactive ion etching (RIE) is then performed to etch off portions of the first layer 902 along the top and bottom of the gate cut opening 502. As a result, the first layer 902 will remain along the sidewalls of the gate cut opening 502. A process such as CVD, ALD or PVD can then be used to deposit the second layer 904 over the first layer 902, followed by CMP, to produce the structure shown in FIG. 11 and FIG. 12.

Referring to FIG. 13 (a top-down view), FIG. 14 (an X cross-sectional view), FIG. 15 (a Y1 cross-sectional view) and FIG. 16 (a Y2 cross-sectional view), a block mask 1302 is formed on the semiconductor device 100, marking the footprint and location of the above-referenced power via. According to an exemplary embodiment, the block mask 1302 includes an organic planarizing layer 1302a disposed on the semiconductor device 100, and an anti-reflective coating 1302b disposed on the organic planarizing layer 1302a.

An etching process such as reactive ion etching is then used to pattern an opening 1304 in the block mask 1302 over the bi-layer dielectric (i.e., first layer 902/second layer 904). Preferably, the opening 1304 is positioned over the bi-layer dielectric only in the region between the gates 106. See, for example, FIG. 16. As such, the opening 1304 is not present in the cut along the gate shown in FIG. 15. As described above, for ease and clarity of depiction, not all of the features of semiconductor device 100 are shown in the top-down views provided herein. For instance, the block mask 1302 is not shown in FIG. 13 in order to better illustrate the positioning of the opening 1304 over the bi-layer dielectric.

Referring to FIG. 17 (a top-down view), FIG. 18 (an X cross-sectional view), FIG. 19 (a Y1 cross-sectional view) and FIG. 20 (a Y2 cross-sectional view), the block mask 1302 is then used to partially recess the second layer 904 of the bi-layer dielectric from the frontside of the wafer 101, thereby forming a via 1702 in between the first layer 902 sidewalls of the bi-layer dielectric. As provided above, the first/second dielectric materials for the bi-layer dielectric can be chosen to impart etch selectivity. For instance, a nitride dielectric material can be chosen as the first dielectric material of first layer 902, and an oxide dielectric material can be chosen as the second dielectric material of second layer 904. In that case, an oxide-selective etching process such as an oxide-selective reactive ion etch can be employed to form the via 1702 in between the (nitride) first layer 902 sidewalls of the bi-layer dielectric.

Preferably, only a partial recess of the second layer 904 is performed, meaning that, following formation of the via 1702, a portion of the second layer 904 remains below the bottom of the via 1702. See, for example, FIG. 20. For instance, according to an exemplary embodiment, a top surface of the partially recessed second layer 904 is now just below a top surface of the STI dielectric 116. In other words, the top surface of the partially recessed second layer 904 is closer to the top surface of the STI dielectric 116 than it is to a bottom surface of the STI dielectric 116.

Little, if any, of the anti-reflective coating 1302b will remain following this recess etch of the second layer 904 of the bi-layer dielectric. What remains of the block mask 1302, namely the organic planarizing layer 1302a, can also then be subsequently removed. By way of example only, the organic planarizing layer 1302a can be removed using a plasma ashing process.

Referring to FIG. 21 (a top-down view), FIG. 22 (an X cross-sectional view), FIG. 23 (a Y1 cross-sectional view) and FIG. 24 (a Y2 cross-sectional view), contact patterning and concurrent metallization are then used to form contacts 2106 to the source/drain regions 110 (also referred to herein as “source/drain contacts”), contacts 2108 to the gates 106 (also referred to herein as “gate contacts”) and a power via 2110. Specifically, standard lithography and etching techniques (see above) are employed to pattern i) trenches 2102 in the interlayer dielectric 126 over the source/drain regions 110, and ii) trenches 2104 in the dielectric caps 128 over the gates 106.

According to an exemplary embodiment, one of the trenches 2102 merges with the via 1702 (now shown with a dotted outline) in the region between the gates 106. See, for example, FIG. 24. This will enable the formation of a power via (see below) that is connected to a given one of the source/drain regions 110 of the semiconductor device 100 through a middle-of-line contact (in this case one of contacts 2106).

Standard metallization processes can be employed to form the contacts 2106 to the source/drain regions 110 in the trenches 2102, the contacts 2108 to the gates 106 in the trenches 2104 and the power via 2110 in the via 1702. For instance, referring to magnified view 2112 in FIG. 23, in this example metallization includes first depositing a silicide liner 2114 into and lining each of the trenches 2102 and 2104 and via 1702, depositing a metal adhesion layer 2116 onto the silicide liner 2114, and then depositing a fill metal 2118 onto the metal adhesion layer 2116. Suitable silicide liner 2114 materials include, but are not limited to, titanium (Ti), nickel (Ni) and/or nickel platinum (NiPt), which can be deposited using a process such as CVD, ALD or PVD. According to an exemplary embodiment, silicide liner 2114 has a thickness of from about 1 nm to about 5 nm. Suitable metal adhesion layer 2116 materials include, but are not limited to, TiN and/or TaN, which can be deposited onto the silicide liner 2114 using a process such as CVD, ALD or PVD. According to an exemplary embodiment, metal adhesion layer 2116 has a thickness of from about 1 nm to about 5 nm. Suitable fill metals 2118 include, but are not limited to, W, Co, Ru and/or Al, which can be deposited onto the metal adhesion layer 2116 using a process such as CVD, ALD, PVD, sputtering, plating, evaporation, ion beam deposition, electron beam deposition, laser assisted deposition, chemical solution deposition, etc. Following deposition, the overburden can be removed using a process such as CMP. In FIG. 24, for example, note how the power via 2110 extends just below the level of the bottom of the source/drain regions 110.

Referring to FIG. 25 (a top-down view), FIG. 26 (an X cross-sectional view), FIG. 27 (a Y1 cross-sectional view) and FIG. 28 (a Y2 cross-sectional view), an interconnect layer 2506 is then formed over the frontside of the semiconductor device 100, a back end of line layer 2508 is formed on the interconnect layer 2506, and the back end of line layer 2508 is bonded to a carrier wafer 2510.

To form the interconnect layer 2506, an interlayer dielectric 2502 is first deposited onto the interlayer dielectric 126 over the semiconductor device 100. For clarity, the terms ‘first’ and ‘second’ may also be used herein when referring to interlayer dielectric 126 and interlayer dielectric 2502, respectively. Suitable interlayer dielectric 2502 materials include, but are not limited to, SiN, SiOC and/or oxide low-κ materials such as SiOx and/or oxide ULK-ILD materials such as pSiCOH, which can be deposited using a process such as CVD, ALD or PVD. Following deposition, the interlayer dielectric 2502 can be planarized using a process such as chemical mechanical polishing.

Standard interconnect structures such as metal lines 2504a and conductive vias 2504b are formed in the interlayer dielectric 2502. To form these interconnect structures, a standard lithography and etching process (see above) is employed to pattern trenches and/or vias in the interlayer dielectric 2502, which are then filled with a metal or combination of metals. Suitable metals include, but are not limited to, copper (Cu), W, Ru and/or Co, which can be deposited using a process such as evaporation, sputtering, ALD, CVD or electrochemical plating. Following deposition, the metal overburden can be removed using a process such as CMP. Prior to depositing the metal(s), an adhesion layer (not shown) can be formed lining the trenches and/or vias. Suitable adhesion layer materials include, but are not limited to, TiN and/or TaN. Additionally, a seed layer (not shown) can also be deposited into and lining the trenches and/or vias prior to metal deposition, e.g., to facilitate plating of the metal.

Back end of line layer 2508 generally includes structures commonly formed in the back end of line during semiconductor device fabrication. Namely, in the back end of line, individual devices such as transistors (in the device layer) get interconnected through a series of metal layers interspersed with dielectric material. For instance, conductive structures like vias and metal lines can be employed to connect a device to one or more other devices, to external connections, and the like, with the metal lines making lateral connections and the vias making vertical connections amongst different metallization levels. Standard metallization techniques can be employed to form the back end of line layer 2508. While the individual interconnects present in back end of line layer 2508 are not specifically shown in the figures, one skilled in the art would understand how such a back end of line layer 2508 is implemented for a given semiconductor device application.

Carrier wafer 2510 is then bonded to the frontside of wafer 101 over back end of line layer 2508. Suitable carrier wafers include, but are not limited to, silicon, silicon carbide and/or glass wafers. As will be described in detail below, the use of carrier wafer 2510 will enable wafer 101 to be flipped, thereby permitting the backside processing for the backside power bar and power rail.

Referring to FIG. 29 (a top-down view), FIG. 30 (an X cross-sectional view), FIG. 31 (a Y1 cross-sectional view) and FIG. 32 (a Y2 cross-sectional view), an etch is next performed to remove the substrate 101a, stopping on the etch stop layer 101b. It is notable that, prior to removing the substrate 101a, the wafer 101 is first flipped meaning that what was once at the bottom of wafer 101 is now on the top, and vice versa. Doing so, enables top-down processing to be performed on the backside of wafer 101. However, for consistency, the figures themselves have not been flipped in the drawings with the express understanding that processes now being performed on the backside of wafer 101 (see label) would in practice be performed from the top-down on a flipped wafer.

As provided above, etch stop layer 101b can be formed from SiGe or an oxide material, and the substrate 101a can be formed from Si. In that case, an Si-selective etch can be used to remove the substrate 101a. Another, e.g., SiGe or oxide-selective, etch can then be performed in turn to remove the etch stop layer 101b. See FIG. 33 (a top-down view), FIG. 34 (an X cross-sectional view), FIG. 35 (a Y1 cross-sectional view) and FIG. 36 (a Y2 cross-sectional view).

Referring to FIG. 37 (a top-down view), FIG. 38 (an X cross-sectional view), FIG. 39 (a Y1 cross-sectional view) and FIG. 40 (a Y2 cross-sectional view), a partial recess of the semiconductor layer 101c is next performed in order to expose a backside of the bi-layer dielectric (i.e., first layer 902/second layer 904). As provided above, the semiconductor layer 101c can be formed from Si. In that case, an Si-selective etch can be employed to recess the semiconductor layer 101c. Since only a partial recess is performed, a portion of the recessed semiconductor layer 101c remains (hereinafter referred to as recessed semiconductor layer 101c′). As will be described in detail below, recessing the semiconductor layer 101c will enable the present backside power bar to be formed in contact with the power via 2110.

Referring to FIG. 41 (a top-down view), FIG. 42 (an X cross-sectional view), FIG. 43 (a Y1 cross-sectional view) and FIG. 44 (a Y2 cross-sectional view), a dielectric cap 4102 is formed on the backside of wafer 101 over the recessed semiconductor layer 101c′. Suitable materials for the dielectric cap 4102 include, but are not limited to, nitride dielectric materials such as SiN. A process such as CVD, ALD or PVD can be used to deposit the dielectric cap 4102, after which the material can be planarized using a process such as CMP. Doing so ensures that the bi-layer dielectric (i.e., first layer 902/second layer 904) remains exposed at the backside of the wafer.

Referring to FIG. 45 (a top-down view), FIG. 46 (an X cross-sectional view), FIG. 47 (a Y1 cross-sectional view) and FIG. 48 (a Y2 cross-sectional view), a (backside) interlayer dielectric 4502 is then deposited onto the dielectric cap 4102. For clarity, the term ‘third’ may also be used herein when referring to interlayer dielectric 4502 so as to distinguish it from the ‘first’ interlayer dielectric 126 and the ‘second’ interlayer dielectric 2502. Suitable interlayer dielectric 4502 materials include, but are not limited to, SiN, SiOC and/or oxide low-κ materials such as SiOx and/or oxide ULK-ILD materials such as pSiCOH, which can be deposited using a process such as CVD, ALD or PVD. Following deposition, the interlayer dielectric 4502 can be planarized using a process such as CMP.

Referring to FIG. 49 (a top-down view), FIG. 50 (an X cross-sectional view), FIG. 51 (a Y1 cross-sectional view) and FIG. 52 (a Y2 cross-sectional view), a block mask 4902 is next formed on the backside of wafer 101 over the interlayer dielectric 4502, and the block mask 4902 is then used to pattern an opening 4904 in the interlayer dielectric 4502 and in the second layer 904 of the bi-layer dielectric.

As above, the block mask 4902 can be formed by an organic planarizing layer that is patterned to mark the footprint and location of the opening 4904. An etching process such as reactive ion etching can then be used to transfer the pattern to the interlayer dielectric 4502 and to the second layer 904 of the bi-layer dielectric, thereby forming opening 4904 therein. Notably, this etch results in opening 4904 being self-aligned to the power via 2110. Namely, as provided above, the dielectric cap 4102, the interlayer dielectric 4502 and the second layer 904 of the bi-layer dielectric can all be formed from oxide dielectric materials, whereas the first layer 902 of the bi-layer dielectric can be formed from a nitride dielectric material. In that case, an oxide-selective reactive ion etch can be employed to form opening 4904 which is positioned in between the sidewalls of the first layer 902 of the bi-layer dielectric, and which is aligned with the power via 2110. This alignment is important as it will ensure that the subsequently formed backside power bar for gate tie down (see below) is well-aligned with the power via 2110. Power via 2110 will connect the backside power bar to the source/drain regions 110 (via the middle-of-line contacts 2106).

In one or more embodiments, to achieve gate tie down, the backside power bar also contacts the gates 106, which can be achieved using selective recess of the first layer 902 of the bi-layer dielectric adjacent to the gates 106 (e.g., by way of a follow-up nitride-selective etch). In that regard, referring to FIG. 53 (a top-down view), FIG. 54 (an X cross-sectional view), FIG. 55 (a Y1 cross-sectional view) and FIG. 56 (a Y2 cross-sectional view), a block mask 5302 is next formed in opening 4904 that is patterned to mark the footprint and location of that recess. As above, the block mask 5302 can be formed by an organic planarizing layer. For illustrative purposes only, the placement of the recess is indicated using dashed box 5304 in FIG. 53.

Referring to FIG. 57 (a top-down view), FIG. 58 (an X cross-sectional view), FIG. 59 (a Y1 cross-sectional view) and FIG. 60 (a Y2 cross-sectional view), an etching process such as reactive ion etching is then used to transfer the pattern from the block mask 5302 to the first layer 902 of the bi-layer dielectric, thereby forming a recess 5702 therein. As provided above, the first layer 902 of the bi-layer dielectric can be formed from a nitride dielectric material. In that case, a nitride-selective reactive ion etch can be employed to form the recess 5702 which exposes a portion of a sidewall of the adjacent gate 106. As will be described in detail below, an extension of the backside power bar that will be formed in this recess 5702 will directly contact the sidewall of that adjacent gate 106 (note the backside gate tie down extension extending from a backside power bar 6102 in FIG. 63).

Following formation of the recess 5702, the block masks 4902 and 5302 can be removed. By way of example only, when formed from an organic planarizing layer, the block masks 4902 and 5302 can be removed using a plasma ashing process. Doing so reopens opening 4904 (see above) and exposes recess 5702.

Referring to FIG. 61 (a top-down view), FIG. 62 (an X cross-sectional view), FIG. 63 (a Y1 cross-sectional view) and FIG. 64 (a Y2 cross-sectional view), the opening 4904 and recess 5702 are then filled with a metal or combination of metals to form a backside power bar 6102 and a backside power rail 6104 in direct contact with one another. Suitable metals include, but are not limited to, Cu, W, Ru and/or Co, which can be deposited into the opening 4904 and recess 5702 using a process such as evaporation, sputtering, ALD, CVD or electrochemical plating. Following deposition, the metal overburden can be removed using a process such as CMP. Prior to depositing the metal(s), an adhesion layer (not shown) can be formed lining the opening 4904 and recess 5702. As provided above, suitable adhesion layer materials include, but are not limited to, TiN and/or TaN. Additionally, a seed layer (not shown) can also be deposited into and lining the opening 4904 and recess 5702 prior to metal deposition, e.g., to facilitate plating of the metal. Note, for example in FIG. 63, how backside power bar 6102 connects to gate 106 of FET 102a from the backside of wafer 101 and, in FIG. 64, how backside power bar 6102 connects to a given one of the source/drain regions 110 of FET 102a from the frontside of wafer 101 by way of the power via 2110.

Finally, referring to FIG. 65 (a top-down view), FIG. 66 (an X cross-sectional view), FIG. 67 (a Y1 cross-sectional view) and FIG. 68 (a Y2 cross-sectional view), a backside power delivery network 6502 is formed on the interlayer dielectric 4502 on the backside of the wafer 101 over the backside power bar 6102 and backside power rail 6104.

Backside power delivery network 6502 generally includes backside interconnect structures such as conductive vias and metal lines commonly formed to interconnect various devices, with the metal lines making lateral connections and the vias making vertical connections amongst different metallization levels. Standard metallization techniques can be employed to form the backside power delivery network 6502. While the individual interconnects present in backside power delivery network 6502 are not specifically shown in the figures, given the teachings herein, one skilled in the art would understand how such a backside power delivery network 6502 is implemented for a given semiconductor device application.

Several notable features of the exemplary semiconductor device 100 design are now apparent. For instance, the backside power bar 6102 serves to connect the backside power rail 6104 to both a given source/drain region 110 and the gate 106 of the (first) FET 102a. For example, referring to FIG. 67, a gate tie down extension 6504 of the backside power bar 6102 (which is formed in the recess 5702 in the first layer 902 of the bi-layer dielectric) directly contacts a portion of a sidewall of the gate 106 of FET 102a.

Referring to FIG. 68, the backside power bar 6102 connects the backside power rail 6104 to the given source/drain region 110 of FET 102a through the power via 2110 and the (middle-of-line) contact 2106 to that given source/drain region 110. Notably, the power via 2110 is offset from the source/drain regions 110 of the FET 102a and the FET 102b by the first layer 902 of the bi-layer dielectric. As described in detail above, this unique configuration of the present power via 2110 and backside power bar 6102 results from the implementation of the bi-layer dielectric (i.e., first layer 902/second layer 904) in the gate cut opening 502 between FET 102a and FET 102b, which enables the formation of the power via 2110 from the frontside of wafer 101, and the formation of the backside power bar 6102 with gate tie down extension 6504 from the backside of wafer 101.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching, which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary semiconductor device 100 includes at least one FET (e.g., FET 102a, FET 102b, etc.) on a frontside of wafer 101; a backside power rail 6104 on a backside of the wafer 101; and a backside power bar 6102 connecting the backside power rail 6104 to a given one of the source/drain regions 110 of the at least one FET from the frontside of the wafer and gate 106 of the at least one FET from the backside of the wafer. For instance, according to one exemplary embodiment, semiconductor device 100 can include at least a (first) FET 102a and (second) FET 102b on the frontside of wafer 101, where FET 102a and FET 102b each both includes a channel (e.g., stack of active layers 104), a gate 106 on the channel, and source/drain regions 110 on opposite ends of the channel; the backside power rail 6104 on the backside of the wafer 101; and the backside power bar 6102 present between the FET 102a and FET 102b, where the backside power bar 6102 connects the backside power rail 6104 to a given one of the source/drain regions 110 and the gate 106 of the FET 102a.

In accordance with further aspects of the present techniques, a method of fabricating a semiconductor device includes: forming at least a (first) FET 102a and (second) FET 102b on the frontside of wafer 101, where FET 102a and FET 102b each both includes a channel (e.g., stack of active layers 104), a gate 106 on the channel, and source/drain regions 110 on opposite ends of the channel; forming a gate cut opening between the gate 106 of the FET 102a and the gate 106 of the FET 102b; forming the power via 2110 in the gate cut opening 502 from the frontside of the wafer 101; and forming the backside power bar 6102 in the gate cut opening 502 from the backside of the wafer 101, where the backside power bar 6102 directly contacts a portion of a sidewall of the gate 106 of the FET 102a.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed backside gate tie down through backside power bar scheme.

An integrated circuit in accordance with aspects of the present inventions can be employed in essentially any application and/or electronic system where one or more aspects of the disclosed backside gate tie down through backside power bar scheme would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor device, comprising:
at least one field-effect transistor (FET) on a frontside of a wafer;
a backside power rail on a backside of the wafer; and
a backside power bar connecting the backside power rail to a source/drain region of the at least one FET from the frontside of the wafer and a gate of the at least one FET from the backside of the wafer.

2. The semiconductor device of claim 1, further comprising:
a power via; and
a middle-of-line source/drain contact in direct contact with the power via, wherein the backside power bar is connected to the source/drain region through the power via and the middle-of-line source/drain contact.

3. The semiconductor device of claim 1, wherein the power via is offset from the source/drain region by a layer of a dielectric material.

4. The semiconductor device of claim 3, wherein the dielectric material comprises a nitride dielectric material.

5. The semiconductor device of claim 1, wherein the backside power bar directly contacts the gate.

6. The semiconductor device of claim 1, wherein the backside power bar directly contacts a portion of a sidewall of the gate.

7. The semiconductor device of claim 6, further comprising:
a bi-layer dielectric adjacent to the gate, wherein the bi-layer dielectric comprises a first layer of a first dielectric material disposed on the sidewall of the gate, and a second layer of a second dielectric material disposed on the first layer of the first dielectric material,
and wherein a gate tie down extension of the backside power bar present in a recess of the first layer of the first dielectric material directly contacts the portion of the sidewall of the gate.

8. The semiconductor device of claim 7, wherein the first dielectric material comprises a nitride dielectric material, and wherein the second dielectric material comprises an oxide dielectric material.

9. The semiconductor device of claim 1, wherein the at least one FET further comprises a stack of active layers which serve as a channel, and wherein the gate surrounds a portion of each of the active layers in a gate-all-around configuration.

10. A semiconductor device, comprising:
at least a first field-effect transistor (FET) and a second FET on a frontside of a wafer, wherein the first FET and the second FET each comprises a channel, a gate on the channel, and source/drain regions on opposite ends of the channel;
a backside power rail on a backside of the wafer; and
a backside power bar present between the first FET and the second FET, wherein the backside power bar connects the backside power rail to a given one of the source/drain regions of the first FET from the frontside of the wafer and the gate of the first FET from the backside of the wafer.

11. The semiconductor device of claim 10, further comprising:
a power via; and
a middle-of-line source/drain contact in direct contact with the power via, wherein the backside power bar is connected to the given source/drain region of the first FET through the power via and the middle-of-line source/drain contact.

12. The semiconductor device of claim 10, wherein the power via is offset from the source/drain region of the first FET and the source/drain region of the second FET by a dielectric material.

13. The semiconductor device of claim 10, wherein the backside power bar directly contacts the gate.

14. The semiconductor device of claim 10, wherein the backside power bar directly contacts a portion of a sidewall of the gate of the first FET.

15. The semiconductor device of claim 14, further comprising:
a bi-layer dielectric between the gate of the first FET and the gate of the second FET, wherein the bi-layer dielectric comprises a first layer of a first dielectric material disposed on the sidewall of the gate of the first FET and on a sidewall of the gate of the second FET, and a second layer of a second dielectric material disposed on the first layer of the first dielectric material,
and wherein a gate tie down extension of the backside power bar present in a recess of the first layer of the first dielectric material disposed on the sidewall of the gate of the first FET directly contacts the portion of the sidewall of the gate of the first FET.

16. The semiconductor device of claim 15, wherein the first dielectric material comprises a nitride dielectric material, and wherein the second dielectric material comprises an oxide dielectric material.

17. A method of fabricating a semiconductor device, the method comprising:
forming at least a first field-effect transistor (FET) and a second FET on a frontside of a wafer, wherein the first FET and the second FET each comprises a channel, a gate on the channel, and source/drain regions on opposite ends of the channel;
forming a gate cut opening between the gate of the first FET and the gate of the second FET;
forming a power via in the gate cut opening from the frontside of the wafer; and
forming a backside power bar in the gate cut opening from a backside of the wafer, wherein the backside power bar directly contacts a portion of a sidewall of the gate of the first FET.

18. The method of claim 17, further comprising:
depositing a bi-layer dielectric into the gate cut opening, wherein the bi-layer dielectric comprises a first layer of a first dielectric material lining the gate cut opening, and a second layer of a second dielectric material disposed on the first layer of the first dielectric material such that the first layer of the first dielectric material is present along sidewalls of the gate cut opening and the second layer of the second dielectric material fully fills the gate cut opening in between the first layer of the first dielectric material;
partially recessing the second layer of the second dielectric material to form a via in between the first layer of the first dielectric material along the sidewalls of the gate cut opening; and
forming the power via in the via.

19. The method of claim 18, wherein the first dielectric material comprises a nitride dielectric material, and wherein the second dielectric material comprises an oxide dielectric material.

20. The method of claim 18, further comprising:
forming a middle-of-line source/drain contact in direct contact with the power via; and
forming a backside power rail on a backside of the wafer, wherein the backside power rail is in direct contact with the backside power bar, and wherein the backside power bar connects the backside power rail to a given one of the source/drain regions of the first FET through the power via and the middle-of-line source/drain contact.
